(19) United States
(12) Patent Application Publication
(10) Pub. No.: US 2024/0402251 A1
(43) Pub. Date: Dec. 5, 2024

(54) MIXED SIGNAL CIRCUIT, METHODS AND DEVICES FOR TESTING MIXED SIGNAL CIRCUITS

(71) Applicant: Intel Corporation, Santa Clara, CA (US)

(72) Inventors: Aryeh FARBER, Petah Tikva (IL); Evgeny SHUMAKER, Nesher (IL); Samer ARRAM, Santa Clara, CA (US); Dana Shalala YETIV, Haifa (IL); Nir GERON, Ramat Efal (IL); Gil HOROVITZ, Emek-Hefer (IL)

(21) Appl. No.: 18/326,039

(22) Filed: May 31, 2023

(51) Int. Cl. G01R 31/319; G01R 31/3193

(52) U.S. Cl. CPC G01R 31/31917; G01R 31/31932

(57) ABSTRACT

A mixed-signal circuit may include an analog circuit and a digital circuit coupled to the analog circuit, wherein the analog circuit is configured to, in a normal operation mode, provide an analog signal to the digital circuit, and wherein the digital circuit is configured to, in the normal operation mode, provide a digital signal to the analog circuit, the mixed-signal circuit may further include a test signal generator configured to, during a test operation mode, receive the digital signal from the digital circuit, generate a test signal based on the digital signal, and provide the test signal to the digital circuit, wherein the test signal generator is configured to generate the test signal using an emulation of the analog circuit, and wherein the mixed-signal circuit is tested based on an output of the digital circuit that is generated in response to the test signal.

### TECHNICAL FIELD

Various aspects of this disclosure generally relate to a mixed-signal circuit, devices and methods for testing a mixed-signal circuit. By way of example, various aspects relate to built-in self-tests for mixed signal circuits, such as for example digital phased locked loops.

### BACKGROUND

An important part of the production process of an integrated circuit (IC) is to thoroughly test the IC to ensure it has no defects or critical bugs. Typically, to guarantee testability, each sub-block of an IC is required to include an embedded Design for Test (DFT).

Special attention is required in a mixed-signal IC, such as for example a digital phase-locked loop (DPLL), in which the digital part of the circuit is driven by analog input signals. In a purely digital system, an output can be predicted for a given input, allowing to test the circuit by using predefined input vectors and comparing the obtained output to the expected result. However, in a mixed-signal circuit where a digital circuit has analog inputs, the output of the circuit becomes unpredictable. Analog signals may vary with e.g. process, voltage and temperature, and are subject to stochastic processes such as cross talk and noise.

Furthermore, in some applications (e.g. automotive and industrial) there is a need to ascertain the integrity of a circuit at each system power up, and not only during the production process. In order to achieve this, a built-in self-test (BIST) mechanism can be used to validate the functionality of each sub-block of a circuit in the field, without the need for test or lab equipment.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. It should be understood that the drawings are diagrammatic and schematic representations of exemplary aspects of the invention, and are neither limitative nor necessarily drawn to scale of the present invention. In the following description, various embodiments of the invention are described with reference to the following drawings, in which:

FIG. 1 shows an exemplary test circuit including a Built-In Self-Test, BIST;

FIG. 2 shows an exemplary test circuit including an analog emulator;

FIG. 3 shows an exemplary digital phase-locked loop, DPLL, circuit;

FIG. 4 shows an exemplary analog emulator;

FIG. 5 shows an exemplary mixed-signal circuit according to some aspects;

FIG. 6 shows a flowchart illustrating a method for testing a mixed-signal circuit according to some aspects; and

FIG. 7 shows an exemplary test device for testing a mixed-signal circuit according to some aspects.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The phrases “group (of)”, “set (of)”, “collection (of)”, “series (of)”, “sequence (of)”, “grouping (of)”, etc., and the like in the description and in the claims, if any, refer to a quantity equal to or greater than one, i.e., one or more.

The phrase “at least one of” with regard to a group of elements may be used herein to mean at least one element from the group including the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit, and may also be referred to as a “processing circuit,” “processing circuitry,” among others. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality, among others, and conversely that any single processor, controller, or logic circuit detailed herein may be realized as two (or more) separate entities with equivalent functionality, among others.

As used herein, “memory” is understood as a computer-readable medium in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” refers to any type of executable instruction, including firmware.

The term “calculate” encompass both ‘direct’ calculations via a mathematical expression/formula/relationship and ‘indirect’ calculations via lookup or hash tables and other array indexing or searching operations. The term “determine” encompass both ‘direct’ determinations via a mathematical expression/formula/relationship and ‘indirect’ determinations via lookup or hash tables and other array indexing or searching operations.

A mixed-signal circuit (such as for example a digital phase locked loop, DPLL) in general includes both analog and digital portions (also called parts and/or blocks in the following).

For example, a DPLL may have an analog portion including a digitally controlled oscillator, DCO, a time-to-digital converter, TDC, a cycle counter, etc., and a digital portion, which may include sequential and combinational logic as well as various types of static and/or dynamic memory cells.

In order to test and ensure that a mixed-signal circuit has no defects (also referred to as errors, faults, or critical bugs in the following) each logic chain and each memory element (e.g. each flip-flop) of the mixed-signal circuit may require the inclusion of an embedded Design for Test, DFT.

Furthermore, in a mixed-signal circuit, it may be provided to discriminate between errors occurring in the digital portion of the circuit, and errors occurring in the analog portion of the circuit.

Hence, various aspects of this disclosure provide different stand-alone methods for testing the analog and digital portion of mixed-signal circuits.

Various aspects of this disclosure provide efficient methods and devices to test a mixed-signal circuit which includes an embedded Built-In Self-Test design (DFT BIST). Various aspects of this disclosure further provide efficient methods and devices to test a mixed-signal circuit (e.g. a DPLL) post fabrication, for example at every startup of the circuit.

A possible test design for testing a circuit during the production process are the so-called “scan chains”. In scan chain testing, each flip-flop of a circuit under test is replaced by a “scan flip-flop”, which is a flip-flop that includes an additional multiplexer at its data input, wherein the multiplexer enables the flip-flop to select between an operation mode or a test mode, also called “scan data input mode” (scan_in). In test mode, all scan_in ports are “chained” together to form a shift register, wherein each flip-flop drives a scan_in port of the following flip-flop until the end of the chain is reached.

The scan chain test infrastructure can generally be resumed by the following four stages:
1. Shift in: while scan mode is enabled all flip-flops are set to pre-defined test vector values by shifting them in through the scan chain;
2. Toggle clock: while scan mode is disabled, the chip clock toggles all flip-flops through their operational data paths;
3. Shift out: once a test is done, the flip-flops outputs are read-out when scan mode is enabled again; and
4. Comparison: the output vector of the flip-flops is compared to an expected output vector.

However, scan chains have several drawbacks. First of all, scan chains have high demands, requiring a multiplexer for every flip-flop to be tested (typically increasing the total gate count of the circuit by 5 to 15%). Scan chains also require dedicated test and/or lab equipment to perform the scan_in and scan_out operations. Such required circuit complexity (scan_in, scan_out, clocks) may not be available in some circuits, and/or may be too costly to implement. This may in particular be the case in mixed-signal circuits such as a DPLL.

A further drawback of scan chains is that they can cause large voltage/IR drops due to each flip-flop toggling at the same time, thus possibly leading to circuit failures that do not occur in operational mode.

Another problem of scan chains is that they are slow. The scan_in and scan-out operations may take many cycle clocks (depending on the number of flip-flops in the scan chain) and produce a large number of test vectors before full test coverage is reached.

Scan chains, while very thorough (each bit can be tested) may also suffer from over-testing, i.e. some bits may be identified by the scan chain as showing a failure, but in operational mode the circuit works fine. This problem may occur if the tested circuit never uses the defected bits in operational mode, and/or if the failing node is not important in operational mode.

In mixed-signal circuits, and in particular in mixed-signal circuits with an analog feedback loop such as a DPLL, it is desirable to drive the circuit during testing (test operation mode) in the same way as the analog portion drives the circuit in operational mode, thus avoiding scanning each node and each flip-flop. Further exemplary mixed-signal circuits may include voltage converters, analog-to-digital converters. In the following, mixed-signal circuit may be understood as every circuit featuring a digital closed-loop decision making process based on an analog behavior.

Lastly, scan chains typically only allow testing during the production process of the circuit, but not afterwards. Applications and circuits may however require testing after production. Therefore, there is a need for alternative ways of testing a circuit post production.

In the following, examples and embodiments of circuits with built-in self-tests capable of testing the circuit after production, for example at every startup, are described in detail.

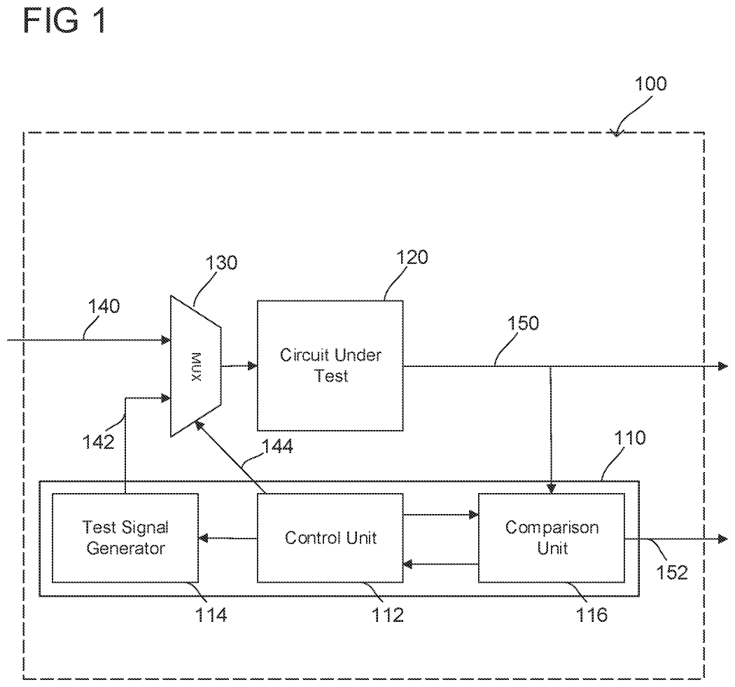

FIG. 1 shows an exemplary test circuit 100 with a Built-In Self-Test, BIST, 110. The circuit 100 further includes a circuit under test, CUT, 120 (or device under test, DUT) and a multiplexer 130.

The BIST 110 includes a control circuit 112, a test signal generator 114 and a comparison circuit 116.

In normal mode of operation, the multiplexer 130 receives an input signal 140, transmits it to the CUT 120, and the CUT 120 outputs an output signal 150.

In test mode of operation, a test signal/vector 142 is generated by the test signal generator 114, and transmitted to the multiplexer 130 and to the CUT 120.

After processing of the test signal 142, the CUT 120 transmits the output signal 150 to the comparison circuit 116. The comparison circuit 116 is configured to compare the output signal 150 to an expected output signal, and to output a pass/fail signal 152. It may further be configured to send the pass/fail signal 152 and/or a signal indicating the result of the comparison to the control circuit 112.

The control circuit 112 is configured to send the expected output signals to the comparison circuit 116, and to instruct the test signal generator 114 to start (stop) generating test signals. The control circuit 112 is further configured to send a test enable (disable) signal 144 to the test signal generator 114 and to the multiplexer 130 (and/or to the CUT 120).

The BIST design of test circuit 100 illustrated in FIG. 1 may however not be well suited for mixed-signal circuits, and in particular for mixed-signal circuits with an analog feedback loop such as a DPLL.

One problem with test circuit 100 is that it generates random vectors (signals) 142. The randomly generated vectors will not match the expected input pattern to the CUT 120 in normal mode of operation of the circuit. As a result, the feedback error signal within the system/circuit may saturate or produce very specific values, i.e. the test will not cover the entire (required) dynamic range for the test signals/vectors.

There is therefore a need to improve on the BIST design of test circuit 100.

In the following, examples and embodiments of an efficient BIST DFT design, as well as corresponding circuits and methods are described. The following circuits and methods allow to test mixed-signal circuits such as a DPLL post fabrication (e.g. at each power up), cause only minimal hardware overhead and require no additional lab/test equipment. They further allow to test the digital and analog portions of a mixed-signal circuit independently.

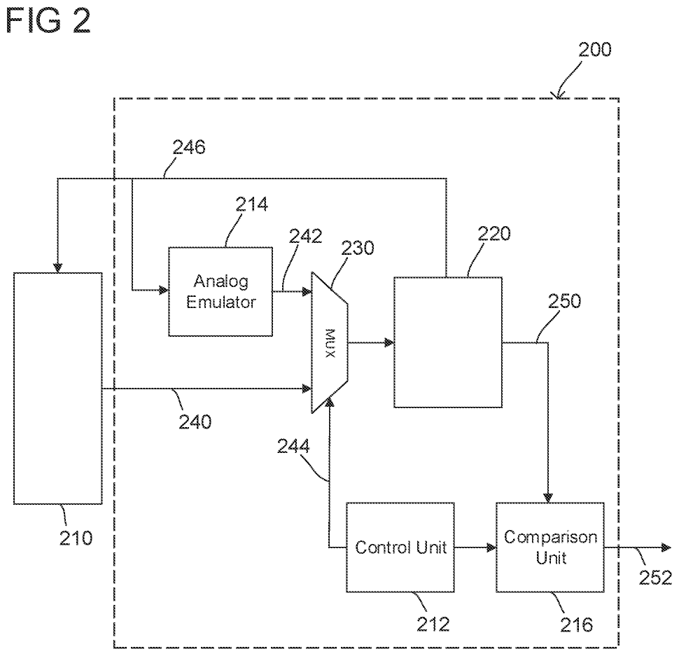

FIG. 2 shows an exemplary test circuit 200 with an analog emulator 214. In the example of FIG. 2, the CUT (or DUT) is a mixed-signal circuit (or device) including an analog portion 210 and a digital portion 220. The test circuit 200 further includes a control circuit 212, a comparison circuit 216 and a multiplexer 230. Optionally, the test circuit 200 may also include the analog portion 210 (not shown in FIG. 2).

In normal mode of operation, the digital portion 220 sends a signal 246 to the analog portion 210. In response, the analog portion 210 sends an analog signal 240 to the multiplexer 230, which transmits it to the digital portion 220 of the circuit.

The CUT and/or the digital portion 220 is further configured to output a signal 250.

In test mode of operation, the (control of the) digital portion 220 of the CUT is configured to send the digital signal 246 to the analog emulator 214. The analog emulator 214 is configured to generate digital test signals/vectors 242 by emulating/mimicking the behavior of the expected analog input signals 240 from the analog portion 210. The analog emulator 214 is further configured to send the generated test signals 242 to the multiplexer 230, which transmits them to the digital portion 220 of the circuit.

In test mode of operation, the digital portion 220 is further configured to send the output signals 250 to the comparison circuit 216. The comparison circuit 216 is configured to compare the received output signals 250 to expected output signals. If the output of the CUT matches the expected output over a predefined number of samples, the comparison circuit 216 (or by the control circuit 212) is further configured to output a pass signal 252. If the output does not match (over a predefined number of samples), a fail signal 252 is output by the comparison circuit 216 (or by the control circuit 212).

The control circuit 212 is configured to send the expected output signals to the comparison circuit 216 and to determine when the test mode of operation is enabled (disabled). To enable (disable) test mode of operation, the control circuit may be configured to send an enable (disable) signal 244 to the multiplexer 230 (and/or to the CUT).

The analog emulator 214 is configured to (analytically) mimic the behavior of each analog circuit present in the analog portion 210 of the CUT. The analog emulator 214 is configured to generate predictable digital input signals (vectors/responses) to the digital stimuli provided by the digital (control) portion 220 of the CUT. The generated digital signals behave in a similar manner to the original input analog signals. Thus, analog emulator 214, rather than generating discrete random test vectors, continuously creates input vectors behaving over time like real operational inputs of a mixed-signal circuit with a feedback loop (such as e.g. a DPLL).

The test circuit 200 of FIG. 2 further allows to test the digital portion 220 of the mixed-signal circuit independently of the analog portion 210. It further allows generating deterministic and expected results, and allows to sweep through all the possible states, i.e. through the entire dynamic range of test signals/vectors.

The test design illustrated in FIG. 2 thus removes the need for any additional scan components, infrastructure and test equipment required for scan chain testing, and enables self-testing of the circuit/device in the field. Furthermore, the circuit will be able to run in the exact same electrical configuration in normal and test mode, with no additional voltage/IR drops.

In the following, the analog emulator will be described in the context of a DPLL. It is appreciated that the following devices, implementations and methods are demonstrative in nature, and are thus understood as capable of being readily applied and/or implemented in other DPLLs, other mixed-signal circuits and/or other devices.

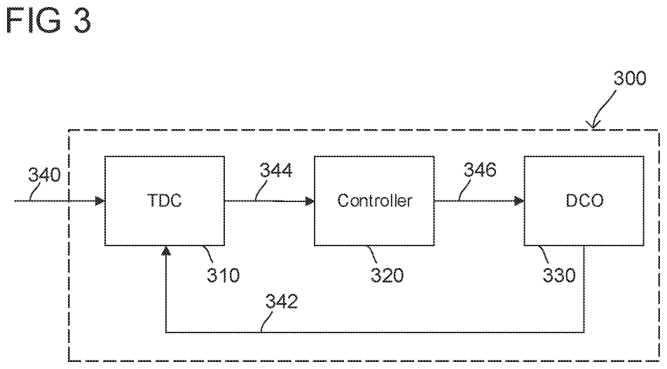

FIG. 3 shows an exemplary digital phase-locked loop, DPLL, circuit 300. The DPLL circuit 300 of FIG. 3 includes a phase detector implemented in the form of a time-to-digital converter, TDC, 310, a controller 320 and a digitally controlled oscillator, DCO, 330. Controller 320 may be implemented in the form of a digital loop filter (not shown in FIG. 3). The DCO 330 may include a digital-to-analog converter and a voltage controlled oscillator (not shown in FIG. 3).

The TDC 310 is configured to receive a reference signal 340 from a reference (not shown in FIG. 3) and a feedback signal 342 from the DCO 330. The TDC 310 is further configured to detect a phase difference between the reference signal 340 and the feedback signal 342 by measuring the time difference between the rising edges (or falling edges) of the reference signal and the feedback signal. The TDC 310 is further configured to output a signal 344 indicative of the phase difference between the reference and feedback signals to the controller 320.

The controller 320 is configured to receive signal 344 indicating the phase difference between reference and feedback signal from the TDC 310, and to output a control signal 346 to the DCO 330 indicating an adjustment (if necessary) of the oscillator signal. In response, the DCO 330 is configured to adjust its oscillator signal and to output the adjusted signal to the TDC 310 (feedback signal 342).

The exemplary DPLL circuit 300 may further include a cycle (analog) counter (not shown in FIG. 3) and/or a (frequency) divider (not shown in FIG. 3).

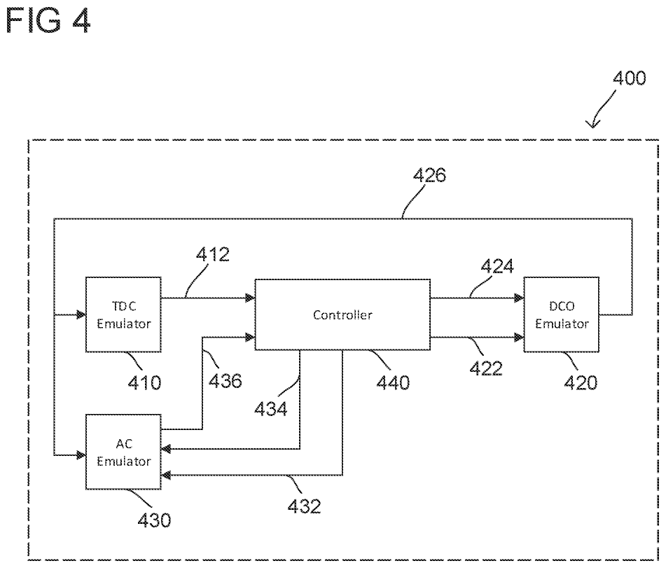

FIG. 4 shows an exemplary analog emulator 400 for a DPLL circuit such as exemplary DPLL circuit 300. Analog emulator 400 may for example correspond to analog emulator 214 illustrated in FIG. 2.

The analog emulator 400 is configured to emulate (analytically mimic) the behavior of the analog portion of a DPLL such as DPLL circuit 300, and includes four sub-blocks:
TDC emulator 410 emulating a time-to-digital converter;
DCO emulator 420 emulating a digitally controlled oscillator;
AC emulator 430 emulating an analog (cycle) counter; and
controller 440, configured to control the operation of the TDC, DCO and AC emulators.

The analog emulator 400 (and/or the controller 440) is further configured to receive the digital output (feedback) signals from the digital portion (e.g. from the controller of the DPLL) of a DPLL circuit such as DPLL circuit 300.

The DCO emulator 420 is configured to emulate the operational output (signals) of the DCO. The DCO emulator 420 receives two signals 422 and 424 from controller 440. The signals 422 and 424 correspond to the “band” and “dlf_out” signal of the DCO, wherein the “band” signal indicates how many coarse capacitors are connected in the DCO, and the “dlf_out” signal indicates how many fine capacitors are connected in the DCO.

The DCO emulator 420 is configured to output a signal 426 \hat{f}ᵢₙₛₜ to the TDC emulator 410, wherein the signal 426 numerically mimics the instantaneous frequency of the DCO, normalized to the reference frequency f_{REF}. Optionally, the DCO emulator 420 may also be configured to output a second signal corresponding to a reference signal (and/or a reference frequency) to the TDC emulator 410 (not shown in FIG. 4).

In the following, a formula for \hat{f}ᵢₙₛₜ is derived.

The DCO instantaneous frequency fᵢₙₛₜ satisfies the following equations:

$${f}_{inst} [ Hz ] = {f}_{base} [ Hz ] + Δ f [ Hz ] ,$$

$$with$$

$$Δ f [ Hz ] = Δ {f}_{BAND} [ Hz ] + Δ {f}_{DLF} [ Hz ] ,$$

$$Δ {f}_{BAND} [ Hz ] = {K}_{BAND} [ \frac{Hz}{code} ] \cdot band ,$$

$$and$$

$$Δ {f}_{DLF} [ Hz ] = {K}_{DLF} [ \frac{Hz}{code} ] \cdot dlf\_out ;$$

where f_{base} is a constant representing the frequency when both “band” and “dlf_out” vectors are zero, and Δf is the instantaneous frequency offset. As can be seen in the above equations, Δf is the sum of the frequency offset caused by the “band” signal, Δf_{BAND}, and the frequency offset caused by the “dlf_out” signal, Δf_{DLF}, wherein K_{BAND} and K_{DLF} represent the frequency offset per band or dlf_code respectively.

The DCO parameters f_{base}, K_{BAND} and K_{DLF} of the DPLL can be normalized to the reference frequency and stored in the available number of fractional bits, “FRAC_WIDTH”, in accordance with the following equations:

$${\hat{f}}_{base} = \frac{{f}_{base}}{{f}_{REF}} \cdot {2}^{FRAC \_ WIDTH} ,$$

$${\hat{K}}_{BAND} = \frac{{K}_{BAND} [ \frac{Hz}{code} ]}{{f}_{REF}} \cdot {2}^{{FRAC}_{WIDTH}} ,$$

$$and$$

$${\hat{K}}_{DLF} = \frac{{K}_{DLF} [ \frac{Hz}{code} ]}{{f}_{REF}} \cdot {2}^{FRAC \_ WIDTH} .$$

The DCO instantaneous frequency difference equation can thus be formulated as:

$${\tilde{f}}_{inst} [ Hz ] = {\tilde{f}}_{base} + \tilde{Δ} f [ n ] ,$$

$$with$$

$$\tilde{Δ} f [ n ] = {\hat{K}}_{BAND} \cdot band [ n ] + {\hat{K}}_{DLF} \cdot dlf [ n ] .$$

The AC emulator 430 is configured to receive signal 426 from the DCO emulator 420, as well as to receive an enabled (disabled) signal 432 and a reset signal 434 from the controller 440. The AC emulator 430 is further configured to count the number of \hat{f}ᵢₙₛₜ cycles every reference cycle it is enabled and to transmit the cycle count to the controller 440 via signal 436.

If the analog count is enabled, i.e. if the enabled signal is received from controller 440, and the reset signal has not been received, the AC emulator 430 is configured to accumulate the instantaneous frequency \hat{f}ᵢₙₛₜ in accordance with the following equation:

$$AC [ n ] = AC [ n - 1 ] + {\tilde{f}}_{inst} [ n ] .$$

The TDC emulator 410 is configured to (analytically) mimic the operation of a TDC. In a DPLL such as DPLL 300, the TDC may be configured to sample the DCO signal and to output a signal (digital code) representing the phase of the DCO signal. Similarly, the TDC emulator 410 is configured to “extract” the DCO emulator phase from signal 426 (\hat{f}ᵢₙₛₜ).

There is a difference between a TDC employed in a divider-less DPLL and a divider based DPLL. While in a divider-less DPLL the DCO phase is measured directly by the TDC, in a divider based DPLL the DCO phase is first divided down and then compared to the reference frequency, and the phase is then measured in the reference frequency domain.

In the following, the “extraction” of the phase in both the divider-less and divider based case are derived.

In a divider-less DPLL, the DCO phase, sampled at each reference clock, can be described as an accumulator of the instantaneous frequency of the DCO:

$$φ [ n ] = φ [ n - 1 ] + {\hat{f}}_{inst} .$$

To account for wrap arounds, the integer part of the phase has to be removed (modulus(2^{FRAC}^{_{WIDTH}})). The phase from 0 to 1 (2π) thus follows the following equation:

$$φ [ n ] = φ [ n - 1 ] + mod ( {\hat{f}}_{inst} , {2}^{{FRAC}_{WIDTH}} ) .$$

If the TDC is a flash TDC configured to output a code normalized to the quantized DCO period P_{DCO}, then the phase can be translated to two output codes corresponding respectively to the rising and falling edges of the DCO:

$${TDC}_{R} [ n ] = min ( {P}_{DCO} \cdot φ [ n ] , mod ( {P}_{DCO} \cdot φ [ n ] + {P}_{DCO} ) ,$$

$$and$$

$${TDC}_{F} [ n ] = min ( {P}_{DCO} \cdot φ [ n ] - 0.5 {P}_{DCO} , mod ( {P}_{DCO} \cdot φ [ n ] + 0.5 {P}_{DCO} ) .$$

With the help of parameter

$${P}_{max} = \frac{1}{{f}_{base} \cdot {T}_{LSB}} ,$$

with f_{base} defined as the longest period required to be supported, the instantaneous DCO period P_{DCO} can be calculated in terms of TDC Least Significant Bits, LSBs, as follows:

$${P}_{DCO} = \frac{1 / {f}_{inst}}{{T}_{LSB}} = {[ \frac{{f}_{inst}}{{f}_{REF}} \cdot {f}_{REF} \cdot {T}_{LSB} ]}^{- 1} = {[ \frac{{f}_{base} + Δ f}{{f}_{REF}} \cdot {f}_{REF} \cdot {T}_{LSB} ]}^{- 1} = \frac{1}{{f}_{base} \cdot {T}_{LSB}} \cdot \frac{1}{1 + \frac{1 Δ f}{{f}_{base}}} \approx {P}_{max} \cdot ( 1 - \frac{Δ f}{{f}_{base}} ) = {P}_{max} \cdot ( 1 - \frac{\tilde{Δ} f}{{f}_{base}} ) = \frac{{P}_{max}}{{\tilde{f}}_{base}} \cdot ( {\tilde{f}}_{base} - ) .$$

In a divider based DPLL, at each TDC sample the time error Δt between the divided DCO phase and the reference clock is provided by the following equation:

$$Δ t [ n ] = Δ t [ n - 1 ] + {N}_{mmd} \frac{1}{{f}_{inst}} - {T}_{REF} ;$$

where N_{mmd} corresponds to the number of DCO pulses in the current cycle and T_{REF} corresponds to the ideal divided clock period when the DPLL is locked (in a locked state).

The above equation can be converted to a normalized phase (between 0 and 1) by dividing the reference period T_{REF}:

$$φ = \frac{Δ L}{{T}_{REF}} = Δ t \cdot {f}_{REF} ,$$

$$φ [ n ] = φ [ n - 1 ] + {N}_{mmd} \frac{{f}_{REF}}{{f}_{inst}} - 1 = φ [ n - 1 ] + \frac{{N}_{mmd}}{( \frac{{f}_{inst}}{{f}_{REF}} )} - 1.$$

The instantaneous frequency is related to the reference frequency via the following equation:

$$\frac{{f}_{inst}}{{f}_{REF}} = ( N + \frac{p}{q} ) = \frac{{\tilde{f}}_{inst}}{{2}^{FRAC \_ WIDTH}} ,$$

where

$$( N + \frac{p}{q} )$$

is an instantaneous varying frequency number.

With the help of the above equation, the phase φ[n] can be rewritten as:

$$φ [ n ] = φ [ n - 1 ] + \frac{{N}_{mmd}}{( N + \frac{p}{q} )} - 1 = φ [ n - 1 ] + \frac{{N}_{mmd} - ( N + \frac{p}{q} )}{( N + \frac{p}{q} )}$$

The phase φ[n] can also be interpreted and represented as a ticks signal, representing how many TDC LSBs are needed for the representation of each phase. To obtain the ticks signals, the phase is multiplied by the quantized reference period by multiplying it with the quantized reference period

$${P}_{REF} \cdot ( \frac{1}{{f}_{REF} {T}_{LSB}} ) : ticks [ n ] = {P}_{REF} \cdot φ [ n ] = {P}_{REF} \cdot φ [ n - 1 ] + ( {N}_{mmd} - ( N + \frac{p}{q} ) ) \frac{{P}_{REF}}{( N + \frac{p}{q} )}$$

The above formula can be rewritten using the earlier derived formulas for \tilde{f}ᵢₙₛₜ, P_{DCO} and P_{REF} into:

$$ticks [ n ] = {P}_{REF} \cdot φ [ n ] = {P}_{REF} \cdot φ [ n - 1 ] + ( {N}_{mmd} - \frac{{\tilde{f}}_{inst}}{{2}^{FRAC \_ WIDTH}} ) \cdot {P}_{DCO}$$

In summary, TDC emulator 410 is configured to emulate (calculate) the phase of signal 426 received from the DCO emulator 420. Afterwards, the TDC emulator 410 is configured to output a signal 412 to controller 440 indicative of the phase of signal 426 and/or indicative of a phase difference between signal 426 and a reference signal.

The analog emulator 400 is thus configured to generate predictable digital input signals, which behave in a similar manner as the original analog signal. Analog emulator 400 may be used for testing a DPLL circuit such as DPLL circuit 300, using for example a test circuit as illustrated in FIG. 2.

Because the digital signals generated by the analog emulator 400 behave over time like real operational inputs of the DPLL, full test coverage can be achieved (i.e. sweeping through all possible states). The test circuit (and method) results in minimal hardware overhead, and removes the need for any additional scan components, infrastructure and test equipment and enables field self-testing.

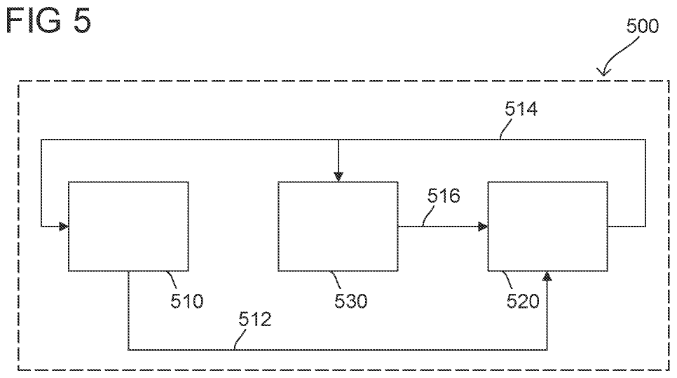

FIG. 5 illustrates an exemplary mixed-signal circuit 500 according to some aspects. As shown in FIG. 5, the mixed-signal circuit 500 includes an analog circuit 510 and a digital circuit 520 coupled to the analog circuit 510, wherein the analog circuit 510 is configured to, in a normal operation mode, provide an analog signal 512 to the digital circuit 520, wherein the digital circuit 520 is configured to, in the normal operation mode, provide a digital signal 514 to the analog circuit 510 (not shown in FIG. 5), the mixed-signal circuit 500 further includes a test signal generator 530 configured to, during a test operation mode, receive the digital signal 514 from the digital circuit 520, generate a test signal 516 based on the digital signal 514, and provide the test signal 516 to the digital circuit 520, wherein the test signal generator 530 is configured to generate the test signal 516 using an emulation of the analog circuit 510.

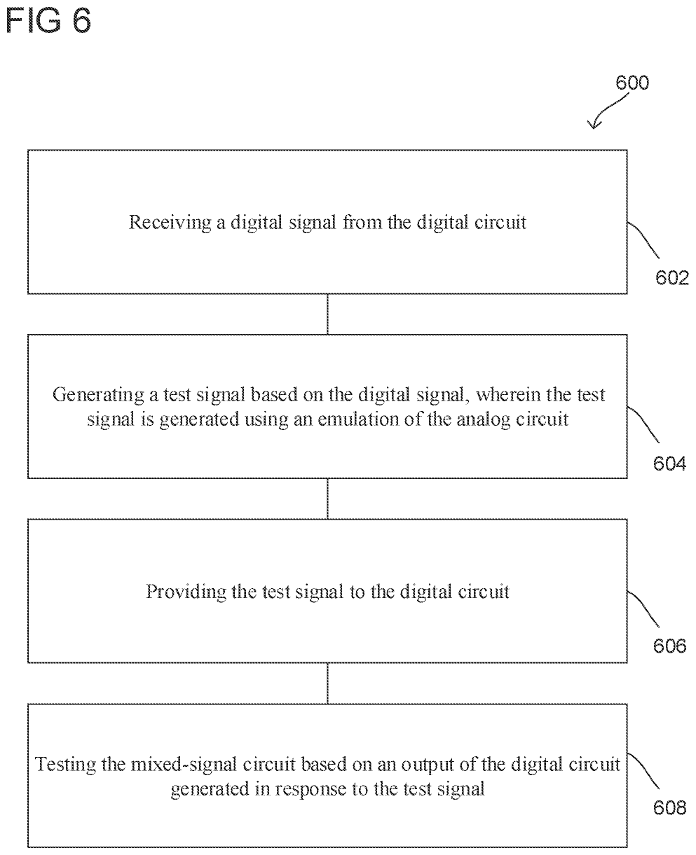

FIG. 6 shows a flowchart illustrating a method 600 of testing a mixed-signal circuit comprising an analog circuit and a digital circuit, such as for example mixed-signal circuit 500 illustrated in FIG. 5. As shown in FIG. 6, the method 600 of testing the mixed-signal circuit includes receiving 602 a digital signal from the digital circuit, generating 604 a test signal based on the digital signal, wherein the test signal is generated using an emulation of the analog circuit, and providing 606 the test signal to the digital circuit.

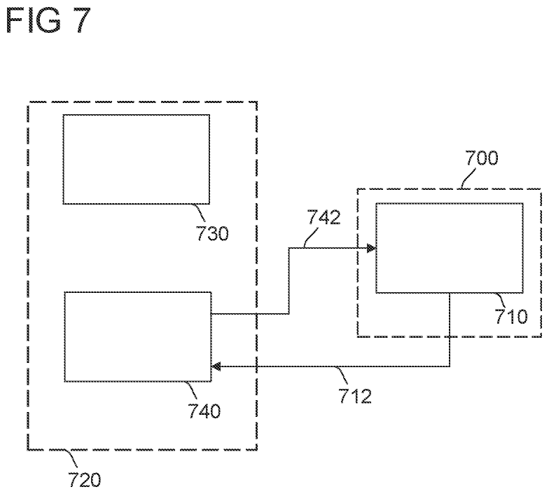

FIG. 7 shows an exemplary test device 700 according to some aspects for testing a mixed-signal circuit 720 comprising an analog circuit 730 and a digital circuit 740. As shown in FIG. 7, the test device 700 includes means 710 for receiving a digital signal 742 from the digital circuit 740; means 710 for generating a test signal 712 based on the digital signal 742; and means 710 for providing the test signal 722 to the digital circuit 740, wherein the test signal 722 is generated using an emulation of the analog circuit 730.

While the above descriptions and connected figures may depict electronic device components as separate elements, skilled persons will appreciate the various possibilities to combine or integrate discrete elements into a single element. Such may include combining two or more circuits to form a single circuit, mounting two or more circuits onto a common semiconductor chip or chassis to form an integrated element, executing discrete software components on a common processor core, etc. Conversely, skilled persons will recognize the possibility to separate a single element into two or more discrete elements, such as splitting a single circuit into two or more separate circuits, separating a semiconductor chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

The following examples disclose various aspects of this disclosure:

Example 1 is a mixed-signal circuit. The mixed-signal circuit may include a an analog circuit and a digital circuit coupled to the analog circuit, wherein the analog circuit is configured to, in a normal operation mode, provide an analog signal to the digital circuit, wherein the digital circuit is configured to, in the normal operation mode, provide a digital signal to the analog circuit, the mixed-signal circuit further includes a test signal generator configured to, during a test operation mode, receive the digital signal from the digital circuit, generate a test signal based on the digital signal, and provide the test signal to the digital circuit, wherein the test signal generator is configured to generate the test signal using an emulation of the analog circuit and wherein the mixed-signal circuit is tested based on an output of the digital circuit that is generated in response to the test signal.

In Example 2, the subject-matter of Example 1 can optionally include that the test signal generator is configured to generate the test signal using a digital emulation of the analog circuit.

In Example 3, the subject-matter of Examples 1 or 2 can optionally include a controller configured to generate a start signal indicating the start of the test operation mode, to receive an output signal from the mixed-signal circuit, and to generate a pass or fail signal based on a comparison of the received output signal and a predefined expected output signal.

In Example 4, the subject-matter of Example 3 can optionally include that the controller is further configured to deactivate the analog circuit during the test operation mode.

In Example 5, the subject-matter of Examples 3 or 4 can optionally include a multiplexer configured to receive the analog signal from the analog circuit, to receive the test signal from the test signal generator, to receive the start signal from the controller, to output, in the normal mode of operation, the analog signal to the digital circuit, and to output, in the test operation mode, the test signal to the digital circuit.

In Example 6, the subject-matter of any one of Examples 1 to 5 can optionally include a controller configured to record the voltage waveform of the signals supplied to the digital and analog circuits, and a memory to store the recorded waveforms.

In Example 7, the subject-matter of any one of Examples 1 to 6 can optionally include that the mixed-signal circuit is a digital phase-lock loop circuit.

In Example 8, the subject-matter of Example 7 can optionally include that the analog circuit includes a digitally controlled oscillator, a cycle counter, and a time-to-digital converter, wherein the emulation of the digitally controlled oscillator is based on numerically approximating the instantaneous frequency of the digitally controlled oscillator, the emulation of the cycle counter is based on summing the numerically approximated instantaneous frequency cycles of the digitally controlled oscillator, and the emulation of the time-to-digital converter is based on determining the phase from the numerically approximated instantaneous frequency of the digitally controlled oscillator.

Example 9 is a method for testing a mixed-signal circuit including an analog circuit and a digital circuit. The method may include receiving a digital signal from the digital circuit, generating a test signal based on the digital signal, providing the test signal to the digital circuit, and testing the mixed-signal circuit based on an output of the digital circuit generated in response to the test signal, wherein the test signal is generated using an emulation of the analog circuit.

In Example 10, the subject-matter of Example 9 can optionally include that the test signal is generated using a digital emulation of the analog circuit.

In Example 11, the subject-matter of Examples 9 or 10 can optionally include generating a start signal indicating the start of a test operation mode for the mixed-signal circuit, receiving an output signal from the mixed-signal circuit, and generating a pass or fail signal based on a comparison of the received output signal and an expected output signal.

In Example 12, the subject-matter of any one of Examples 9 to 11 can optionally include deactivating the analog circuit during the test operation mode.

In Example 13, the subject-matter of any one of Examples 9 to 12 can optionally include recording the voltage waveform of the signals supplied to the digital and analog circuits, and storing the recorded waveforms.

In Example 14, the subject-matter of any one of Examples 9 to 13 can optionally include that the mixed-signal circuit is a digital phase-lock loop circuit.

In Example 15, the subject-matter of Example 14 can optionally include that the analog circuit includes a digitally controlled oscillator, a cycle counter, and a time-to-digital converter, wherein emulating the digitally controlled oscillator is based on numerically approximating the instantaneous frequency of the digitally controlled oscillator, emulating the cycle counter is based on summing the numerically approximated instantaneous frequency cycles of the digitally controlled oscillator, and emulating the time-to-digital converter is based on determining the phase from the numerically approximated instantaneous frequency of the digitally controlled oscillator.

Example 16 is a non-transitory computer readable medium. The non-transitory computer readable medium may include instructions which, when executed by one or more processors, are configured to cause the one or more processors to implement a method for testing a mixed-signal circuit including an analog circuit and a digital circuit, wherein the method includes receiving a digital signal from the digital circuit, generating a test signal based on the digital signal, providing the test signal to the digital circuit, and testing the mixed-signal circuit based on an output of the digital circuit generated in response to the test signal, wherein the test signal is generated using an emulation of the analog circuit.

In Example 17, the subject-matter of Example 16 can optionally include that the instructions are further configured to cause the one or more processors to generate the test signal using a digital emulation of the analog circuit.

In Example 18, the subject-matter of Examples 16 or 17 can optionally include that the instructions are further configured to cause the one or more processors to generate a start signal indicating the start of a test operation mode for the mixed-signal circuit, receive an output signal from the mixed-signal circuit, and generate a pass or fail signal based on a comparison of the received output signal and an expected output signal.

In Example 19, the subject-matter of any one of Examples 16 to 18 can optionally include that the instructions are further configured to cause the one or more processors to deactivate the analog circuit during the test operation mode.

In Example 20, the subject-matter of any one of Examples 16 to 19 can optionally include that the instructions are further configured to cause the one or more processors to record the voltage waveform of the signals supplied to the digital and analog circuits, and to store the recorded waveforms in a memory.

In Example 21, the subject-matter of any one of Examples 16 to 20 can optionally include that the mixed-signal circuit is a digital phase-lock loop circuit.

In Example 22, the subject-matter of Example 21 can optionally include that the analog circuit includes a digitally controlled oscillator, a cycle counter, and a time-to-digital converter, wherein the instructions are further configured to cause the one or more processors to emulate the digitally controlled oscillator based on numerically approximating the instantaneous frequency of the digitally controlled oscillator, to emulate the cycle counter based on summing the numerically approximated instantaneous frequency cycles of the digitally controlled oscillator, and to emulate the time-to-digital converter based on determining the phase from the numerically approximated instantaneous frequency of the digitally controlled oscillator.

Example 23 is a test device for testing a mixed-signal circuit including an analog circuit and a digital circuit. The test device may include means for receiving a digital signal from the digital circuit, means for generating a test signal based on the digital signal, and means for providing the test signal to the digital circuit, wherein the test signal is generated using an emulation of the analog circuit and wherein the mixed-signal circuit is tested based on an output of the digital circuit generated in response to the test signal.

In Example 24, the subject-matter of Example 23 can optionally include that the test signal is generated using a digital emulation of the analog circuit.

In Example 25, the subject-matter of Examples 23 or 24 can optionally include means to generate a start signal indicating the start of a test operation mode, means to receive an output signal from the mixed-signal circuit, and means to generate a pass or fail signal based on a comparison of the received output signal and a predefined expected output signal.

In Example 26, the subject-matter of any one of Examples 23 to 25 can optionally include means to deactivate the analog circuit during the test operation mode.

In Example 27, the subject-matter of Examples 25 or 26 can optionally include means to receive the analog signal from the analog circuit, means to receive the test signal from the test signal generator, means to receive the start signal from the controller, means to output the analog signal to the digital circuit, and means to output the test signal to the digital circuit.

In Example 28, the subject-matter of any one of Examples 23 to 27 can optionally include means to record the voltage waveform of the signals supplied to the digital and analog circuits, and means to store the recorded waveforms.

In Example 29, the subject-matter of any one of Examples 23 to 28 can optionally include that the mixed-signal circuit is a digital phase-lock loop circuit.

In Example 30, the subject-matter of Example 29 can optionally include that the analog circuit includes a digitally controlled oscillator, a cycle counter, and a time-to-digital converter, wherein the test device includes means to emulate the digitally controlled oscillator on the basis of numerically approximating the instantaneous frequency of the digitally controlled oscillator, means to emulate the cycle counter on the basis of summing the numerically approximated instantaneous frequency cycles of the digitally controlled oscillator, and means to emulate the time-to-digital converter on the basis of determining the phase from the numerically approximated instantaneous frequency of the digitally controlled oscillator.

In Example 31, the subject-matter of any one of Examples 23 to 30 can optionally include that the test device is a build-in self-test device.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A mixed-signal circuit comprising:
an analog circuit; and
a digital circuit coupled to the analog circuit;
wherein the analog circuit is configured to, in a normal operation mode, provide an analog signal to the digital circuit;
wherein the digital circuit is configured to, in the normal operation mode, provide a digital signal to the analog circuit;
the mixed-signal circuit further comprising:
a test signal generator configured to, during a test operation mode:
receive the digital signal from the digital circuit;
generate a test signal based on the digital signal; and
provide the test signal to the digital circuit;
wherein the test signal generator is configured to generate the test signal using an emulation of the analog circuit, and
wherein the mixed-signal circuit is tested based on an output of the digital circuit that is generated in response to the test signal.

2. The mixed-signal circuit of claim 1,
wherein the test signal generator is configured to generate the test signal using a digital emulation of the analog circuit.

3. The mixed-signal circuit of claim 1, further comprising a controller configured to:
generate a start signal indicating the start of the test operation mode;
receive an output signal from the mixed-signal circuit; and
generate a pass or fail signal based on a comparison of the received output signal and a predefined expected output signal.

4. The mixed-signal circuit of claim 3, wherein the controller is further configured to deactivate the analog circuit during the test operation mode.

5. The mixed-signal circuit of claim 3, further comprising a multiplexer configured to:
receive the analog signal from the analog circuit, the test signal from the test signal generator, and the start signal from the controller;
output, in the normal mode of operation, the analog signal to the digital circuit; and
output, in the test operation mode, the test signal to the digital circuit.

6. The mixed-signal circuit of claim 1, further comprising:
a controller configured to record the voltage waveform of the signals supplied to the digital and analog circuits; and
a memory storing the recorded waveforms.

7. The mixed-signal circuit of claim 1,
wherein the mixed-signal circuit is a digital phase-lock loop circuit.

8. The mixed-signal circuit of claim 7, wherein the analog circuit comprises:
a digitally controlled oscillator;
a cycle counter; and
a time-to-digital converter;
wherein the emulation of the digitally controlled oscillator is based on numerically approximating the instantaneous frequency of the digitally controlled oscillator,
the emulation of the cycle counter is based on summing the numerically approximated instantaneous frequency cycles of the digitally controlled oscillator, and
the emulation of the time-to-digital converter is based on determining the phase from the numerically approximated instantaneous frequency of the digitally controlled oscillator.

9. A method of testing a mixed-signal circuit comprising an analog circuit and a digital circuit, the method comprising:
receiving a digital signal from the digital circuit;
generating a test signal based on the digital signal;
providing the test signal to the digital circuit; and
testing the mixed-signal circuit based on an output of the digital circuit that is generated in response to the test signal,
wherein the test signal is generated using an emulation of the analog circuit.

10. The method of claim 9, wherein the test signal is generated using a digital emulation of the analog circuit.

11. The method of claim 9, further comprising:
generating a start signal indicating the start of a test operation mode for the mixed-signal circuit;
receiving an output signal from the mixed-signal circuit; and
generating a pass or fail signal based on a comparison of the received output signal and an expected output signal.

12. The method of claim 9, further comprising:
deactivating the analog circuit during the test operation mode.

13. The method of claim 9, further comprising:
recording the voltage waveform of the signals supplied to the digital and analog circuits; and
storing the recorded waveforms in a memory.

14. A non-transitory computer readable medium comprising instructions which, when executed by one or more processors, are configured to cause the one or more processors to implement a method for testing a mixed-signal circuit comprising an analog circuit and a digital circuit, the method comprising:
receiving a digital signal from the digital circuit;
generating a test signal based on the digital signal;
providing the test signal to the digital circuit; and
testing the mixed-signal circuit based on an output of the digital circuit that is generated in response to the test signal,
wherein the test signal is generated using an emulation of the analog circuit.

15. The non-transitory computer readable medium of claim 14, wherein the instructions are further configured to cause the one or more processors to:
generate the test signal using a digital emulation of the analog circuit.

16. The non-transitory computer readable medium of claim 14, wherein the instructions are further configured to cause the one or more processors to:
generate a start signal indicating the start of a test operation mode for the mixed-signal circuit;
receive an output signal from the mixed-signal circuit; and
generate a pass or fail signal based on a comparison of the received output signal and an expected output signal.

17. The non-transitory computer readable medium of claim 14, wherein the instructions are further configured to cause the one or more processors to:
deactivate the analog circuit during the test operation mode.

18. The non-transitory computer readable medium of claim 14, wherein the instructions are further configured to cause the one or more processors to:
record the voltage waveform of the signals supplied to the digital and analog circuits; and
store the recorded waveforms in a memory.
